(19) United States
(12) Patent Application Publication
(10) Pub. No.: US 2024/0136479 A1
(43) Pub. Date: Apr. 25, 2024

(54) LIGHT EMITTING DEVICE

(71) Applicant: LITE-ON TECHNOLOGY CORPORATION, TAIPEI CITY (TW)

(72) Inventors: MIAO-SAN CHIEN, Hsinchu County (TW); Kai-Chieh Liang, New Taipei City (TW); KUO-MING CHIU, New Taipei City (TW)

(21) Appl. No.: 18/405,060

(22) Filed: Jan. 5, 2024

Related U.S. Application Data
(63) Continuation-in-part of application No. 18/108,872, filed on Feb. 13, 2023.
(60) Provisional application No. 63/465,884, filed on May 12, 2023.
(60) Provisional application No. 63/309,755, filed on Feb. 14, 2022.
(60) Provisional application No. 63/331,907, filed on Apr. 18, 2022.

(30) Foreign Application Priority Data
Oct. 20, 2022 (CN) 202211294105.3
Feb. 8, 2023 (CN) 202310089678.0
Sep. 26, 2023 (CN) 202311264102.X

(51) Int. Cl. H01L 33/52; H01L 25/075; H01L 25/16; H01L 33/48; H01L 33/60; H01L 33/62

(52) U.S. Cl. CPC H01L 33/52; H01L 25/0753; H01L 25/167; H01L 33/486; H01L 33/60; H01L 33/62

(57) ABSTRACT

A light emitting device includes a substrate, a wall, at least one light emitting chip, a protection layer, and a reflection layer. The substrate has a mounting surface. The wall is disposed on the mounting surface and has an inner side surface. An accommodation space is defined by the inner side surface and the mounting surface. The light emitting chip has a top light emitting surface and a side light emitting surface, and is disposed in the accommodation space and on the mounting surface. The protection layer is disposed on the top light emitting surface and the side light emitting surface. A gap is formed between the protection layer and the wall. The reflection layer is disposed in the accommodation space and between the inner side surface and the side light emitting surface. The reflection layer is filled in the gap and contacts the mounting surface.

### CROSS-REFERENCE TO RELATED PATENT APPLICATION

This application is a continuation-in-part application of the U.S. patent application Ser. No. 18/108,872, filed on Feb. 13, 2023, and entitled “SEMICONDUCTOR ASSEMBLY,” now pending, the entire disclosures of which are incorporated herein by reference.

This application claims the benefit of priorities to U.S. Provisional Patent Application Ser. No. 63/465,884, filed on May 12, 2023, and China Patent Application No. 202311264102.X, filed on Sep. 27, 2023, in the People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a light emitting device, and more particularly to a light emitting device that has good reliability and peeling strength.

### BACKGROUND OF THE DISCLOSURE

A light emitting diode (LED) has advantages of low energy consumption, long service life, and high luminous efficiency. By using different semiconductor materials, the LED can generate various lights that have different wavelengths. Therefore, the LED can be applied in a lighting emitting device as a light source.

Materials and metal electrodes in the LED are easily oxidized by water vapor and oxygen in the environment. Therefore, the LED is usually encapsulated by a silicone resin acting as an encapsulant to prevent the LED from contacting water vapor and oxygen.

Compared to C—C bond (bond energy: 145 kcal/mol) in organic materials, Si—O bond (bond energy: 193.5 kcal/mol) in the silicone resin has higher bond energy. In addition, a bonding force between the silicone resin and a substrate is high.

In the field of UV light emitting diodes, a fluorine-base resin can be used to protect a LED chip. In response to different optical requirements, the silicone resin can be directly disposed onto the fluorine-base resin. However, a bonding force between the silicone resin and the fluorine-base resin is low, such that delamination may easily occur between layers of the silicone resin and the fluorine-base resin.

Therefore, how to enhance the reliability of the light emitting device by improving the structure or the material of the light emitting device has become one of the important issues to be solved in the industry. In this way, the light emitting device may be capable of operating with high power at a high temperature and a high humidity environment, while still maintaining its structural integrity.

### SUMMARY OF THE DISCLOSURE

In response to the above-referenced technical inadequacy, the present disclosure provides a light emitting device.

In order to solve the above-mentioned problem, one of the technical aspects adopted by the present disclosure is to provide a light emitting device. The light emitting device includes a substrate, a wall, at least one light emitting chip, a protection layer, and a reflection layer. The substrate has a mounting surface. The wall is disposed on the mounting surface and has an inner side surface. An accommodation space is defined by the inner side surface and the mounting surface. The at least one light emitting chip is disposed on the mounting surface and in the accommodation space. The light emitting chip has a top light emitting surface and a side light emitting surface. The protection layer is disposed on the top light emitting surface and the side light emitting surface. A gap is formed between the protection layer and the wall. The reflection layer is disposed in the accommodation space and between the inner side surface and the side light emitting surface. The reflection layer is filled in the gap and contacts the mounting surface.

Therefore, in the light emitting device provided by the present disclosure, by virtue of “a protection layer being disposed on the top light emitting surface and the side light emitting surface” and “a gap being formed between the protection layer and the wall,” the light emitting device can have good reliability and peeling strength.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of a light emitting device according to a first embodiment of the present disclosure;

FIG. 2A and FIG. 2B are schematic cross-sectional views of preparation steps of the light emitting device in FIG. 1;

FIG. 3 is a schematic cross-sectional view of the light emitting device according to a second embodiment of the present disclosure;

FIG. 4 is a schematic top view of the light emitting device according to the second embodiment of the present disclosure;

FIG. 5 is a schematic cross-sectional view of the light emitting device according to a third embodiment of the present disclosure;

FIG. 6 is a schematic top view of the light emitting device according to the third embodiment of the present disclosure;

FIG. 7 is a schematic top view of the light emitting device according to a fourth embodiment of the present disclosure;

FIG. 8 is a schematic cross-sectional view of the light emitting device according to a fifth embodiment of the present disclosure;

FIG. 9 is a schematic top view of the light emitting device according to the fifth embodiment of the present disclosure;

FIG. 10 is a schematic cross-sectional view of a light emitting device according to a first comparative embodiment; and

FIG. 11 is a schematic cross-sectional view of a light emitting device according to a second comparative embodiment.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

In order to overcome the problem of low reliability in a conventional light emitting device, the present disclosure provides a light emitting device in which a light emitting chip is protected by a protection layer from contacting water vapor or oxygen. Moreover, the protection layer can be selectively disposed to cover a part of a substrate.

Due to differences in materials, a bonding force between a reflection layer and the protection layer is lower than a bonding force between the reflection layer and the substrate. Therefore, when the substrate is not completely covered by the protection layer, a certain contact area between the reflection layer and the substrate can be ensured. Accordingly, delamination of the reflection layer can be prevented during a use of the light emitting device.

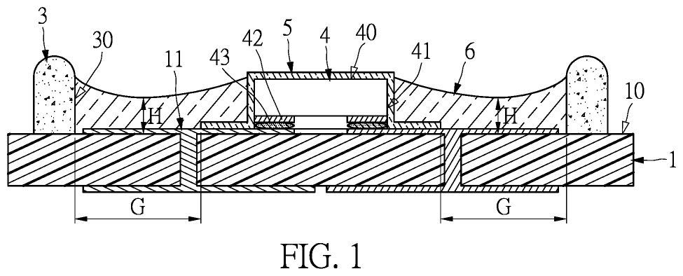

Referring to FIG. 1, the light emitting device of the present disclosure includes a substrate 1, a wall 3, at least one light emitting chip 4, a protection layer 5, and a reflection layer 6.

The substrate 1 has a mounting surface 10. The substrate 1 can be a ceramic substrate, an aluminum nitride substrate, or an aluminum oxide substrate, but the present disclosure is not limited thereto.

A conductive circuit structure 11 is disposed on the substrate 1. The at least one light emitting chip 4 can be electrically connected with an outer circuit via the conductive circuit structure 11.

The conductive circuit structure 11 can include one or more conductive circuits. In addition to being disposed on the mounting surface 10, the conductive circuit structure 11 can also be embedded on the substrate 1 and extend to a bottom surface (i.e., a surface opposite to the mounting surface 10) of the substrate 1. For example, the conductive circuit can be embedded on the substrate 1 and forms an “H” shape as shown in FIG. 1, but the present disclosure is not limited thereto. In this way, the mounting surface 10 and the bottom surface of the substrate 1 can be electrically connected via the conductive circuit structure 11.

The wall 3 is disposed on the mounting surface 10 and has an inner side surface 30. An accommodation space is defined by the inner side surface 30 and the mounting surface 10. The light emitting chip 4, the protection layer 5, and the reflection layer 6 are disposed in the accommodation space.

A height of the wall 3 is higher than or equal to a height of the light emitting chip 4, so as to reflect a light beam generated from the light emitting chip 4 and enhance a luminous efficiency of the light emitting device. In other embodiments, the substrate 1 and the wall 3 are integrally formed, but the present disclosure is not limited thereto.

In other embodiments, the wall 3 is absent from the light emitting device. For example, in some miniaturized light emitting devices, the wall 3 is formed on a connection pad of the conductive circuit structure 11 during a manufacturing process. After the reflection layer 6 is formed, the wall 3 can be removed to expose the connection pad. In this way, a size of the light emitting device can be decreased.

The at least one light emitting chip 4 is disposed in the accommodation space and on the mounting surface 10. Specifically, the at least one light emitting chip 4 can be fixed on the mounting surface 10 (or the conductive circuit structure 11) via a conductive material so as to electrically connect with other elements. The conductive material can be a solder pad 42, a metal solder 43, or other conductive materials which can fix the light emitting chip 4. The metal solder 43 can be a silver solder, a gold solder, or a tin solder. However, the present disclosure is not limited thereto. A solder can also be used to fix the light emitting chip 4.

In the present disclosure, a quantity of the at least one light emitting chip 4 can be one (as in a first embodiment) or more than one (as in a second embodiment to a fifth embodiment). Each light emitting chip 4 has a top light emitting surface 40 and a side light emitting surface 41. The top light emitting surface 40 is disposed on a side opposite to the mounting surface 10, and the side light emitting surface 41 faces toward the inner side surface 30.

For example, the at least one light emitting chip 4 can be, but is not limited to, a horizontal LED chip, a vertical LED chip, or a flip-chip LED chip. In an exemplary embodiment, the at least one light emitting chip 4 can generate a UV light beam. Specifically, the light emitting device can be used to protect a UV light emitting chip, especially for a UVC light emitting chip. In other applications, the light emitting chip 4 can also be a visible light emitting chip or an infrared light diode chip.

The protection layer 5 is a light-transmitting resin layer. The disposition of the protection layer 5 can protect the light emitting chip 4 from contacting water vapor and oxygen. A material of the protection layer 5 can be selected from the group consisting of a fluorine resin, a silicone oil, and silicon dioxide. The silicone oil can be used as a liquid protection layer. Silicon dioxide can be used as a passivation layer by forming a glass membrane onto the light emitting chip 4. Preferably, the material of the protection layer 5 is the fluorine resin.

The protection layer 5 is disposed on the top light emitting surface 40 and the side light emitting surface 41. In addition, the protection layer 5 can also selectively extend from the side light emitting surface 41 toward the conductive material (e.g., the solder pad 42 and the metal solder 43), and further disposed on the mounting surface 10 that surrounds the light emitting chip 4, or be selectively disposed on a part of the conductive circuit structure 11 of the substrate 1.

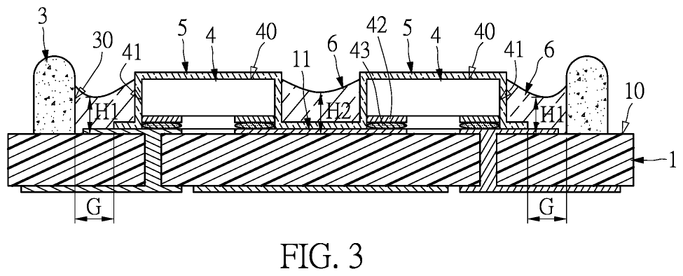

Referring to FIG. 3, when the quantity of the at least one light emitting chip 4 is more than one, the top light emitting surface 40 and the side light emitting surface 41 of each of the light emitting chips 4 are covered by the protection layer 5. Since the protection layer 5 can be selectively disposed on the mounting surface 10 that surrounds the light emitting chip 4, the protection layer 5 can be continuously or discontinuously disposed on the mounting surface 10 according to different placement areas.

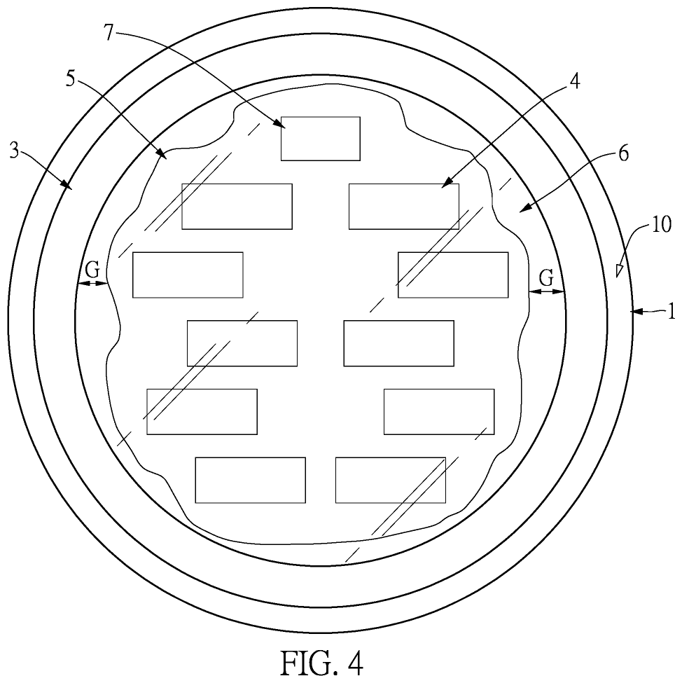

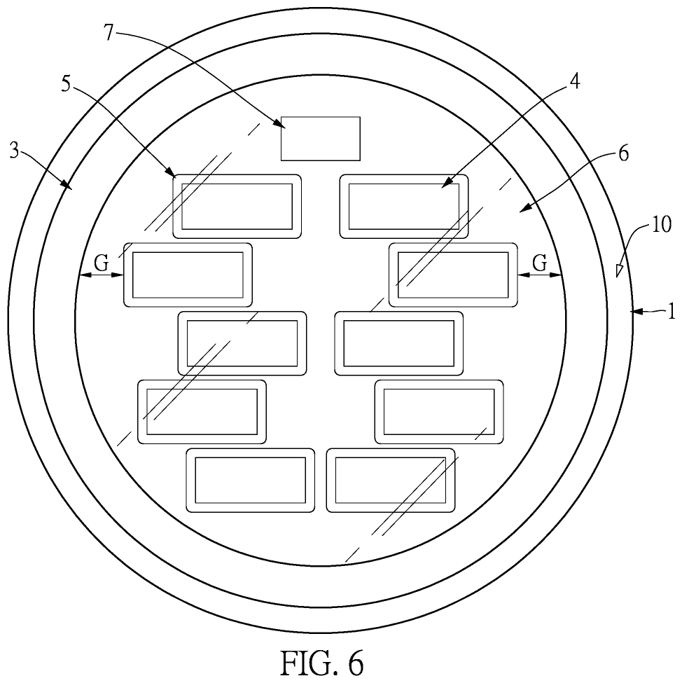

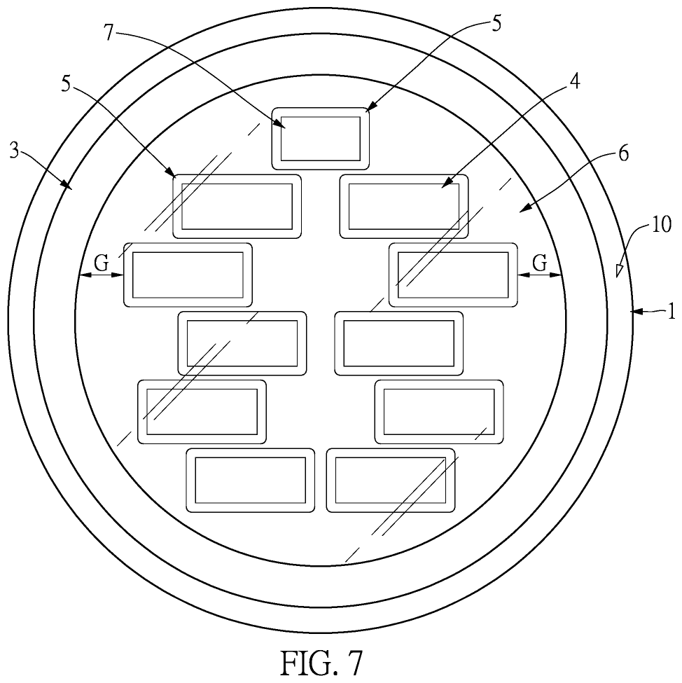

When the protection layer 5 is continuously disposed on the mounting surface 10, the protection layers 5 disposed on the light emitting chips 4 are integrally connected with each other, thereby forming a continuous structure (as shown in FIG. 4). When the protection layer 5 is discontinuously disposed on the mounting surface 10, the protection layers 5 disposed on the light emitting chips 4 are separated from each other, thereby forming a plurality of island-like areas (as shown in FIG. 6 or FIG. 7).

The reflection layer 6 can reflect and concentrate a light beam. The reflection layer 6 is disposed in the accommodation space, and is disposed between the inner side surface 30 and the side light emitting surface 41.

The reflection layer 6 has a concave surface formed between the wall 3 and the light emitting chip 4. The concave surface facilitates concentration of a light beam, so as to enhance the luminous efficiency of the light emitting device. Relative to the mounting surface 10, a height of the reflection layer 6 near the side light emitting surface 41 is lower than a height of the reflection layer 6 near the inner side surface 30.

In an exemplary embodiment, a lowest height H of the reflection layer 6 is higher than half of the height of the light emitting chip 4. Therefore, a light beam generated from the light emitting chip 4 can be well reflected by the reflection layer 6, such that the light emitting device can have a good luminous efficiency. The lowest height H mentioned herein refers to a lowest height of the reflection layer 6 relative to the mounting surface 11 (as shown in FIG. 1).

In addition to the lowest height H, an overall thickness of the reflection layer 6 also influences the luminous efficiency of the light emitting device. When the thickness of the reflection layer 6 is too large, the luminous efficiency of the light emitting device is decreased. Therefore, the thickness of the reflection layer 6 relative to the mounting surface 11 needs to be less than 400 μm. When the thickness of the reflection layer 6 is too small, a light beam cannot be concentrated when passing through the reflection layer 6. Therefore, the thickness of the reflection layer 6 relative to the mounting surface 11 needs to be greater than 250 μm. In the present disclosure, the thickness of the reflection layer 6 refers to a thickness of the reflection layer 6 near the side light emitting surface 41.

Specifically, a material of the reflection layer 6 includes a base resin, a UV absorber, and light reflective particles. The base resin is a silicon-base resin. The base resin can optionally be a silicon-base resin including a methyl group or a thermosetting silicon-base resin according to practical requirements. For example, the base resin can be a methyl silicon resin, a methyl phenyl vinyl silicon resin, or a combination thereof.

The UV absorber can absorb UV light, especially for UV light that has a wavelength ranging from 250 nm to 400 nm, and can convert light energy of the UV light into heat energy. When the base resin is exposed to light, the UV absorber can prevent the base resin from bond breakages through a chemical absorption mechanism.

The reflective particles can enhance light reflectivity through a physical reflection mechanism. The reflective particles can also prevent the base resin from bond breakages when the base resin is exposed to light. A particle size of the reflective particles ranges from 0.2 μm to 20 μm. When the particle size of the reflective particles is too small, the reflective particles cannot be easily and uniformly mixed with other components, thereby leading to a poor reflection effect. When the particle size of the reflective particles is too large, the reflective particles may easily settle down, thereby causing the reflection layer 6 to have a poor reflection effect at its bottom portion. For example, the reflective particles can be polytetrafluoroethylene (PTFE) particles or zirconium dioxide particles. Preferably, the reflective particles are PTFE particles. However, the present disclosure is not limited thereto.

In an exemplary embodiment, based on a total weight of the base resin being 100 phr, an amount of the UV absorber ranges from 0.1 phr to 15 phr. If the amount of the UV absorber is excessive, too much light may be absorbed by the UV absorber, thereby decreasing the brightness of the light emitting device. In addition, a solvent of the UV absorber tends to dilute with the silicon-base resin, so that the silicon-base resin is not easily cured. If the amount of the UV absorber is insufficient, the UV light may degrade the silicon-base resin, thereby negatively affecting the reliability of the light emitting device.

In an exemplary embodiment, based on the total weight of the base resin being 100 phr, an amount of the reflective particles ranges from 5 phr to 75 phr, and preferably ranges from 25 phr to 50 phr. An overly high amount of the reflective particles causes a high viscosity, so that the material of the reflection layer 6 cannot be easily dispensed. However, if the amount of the reflective particles is insufficient, the luminous efficiency of the light emitting device cannot be effectively enhanced.

In addition to the base resin, the UV absorber, and the reflective particles, the reflection layer 6 can further include a hindered amine light stabilizer (HALS). The hindered amine light stabilizer can repair bond breakages, so that the hindered amine light stabilizer can also prevent the base resin from bond breakages.

In an exemplary embodiment, based on the total weight of the base resin being 100 phr, an amount of the HALS ranges from 0.1 phr to 15 phr. If the amount of the HALS is excessive, a solvent of the HALS may dilute with the silicon-base resin, so that the silicon-base resin is not easily cured. If the amount of the HALS is insufficient, the reliability of the light emitting device cannot be improved.

It should be noted that the protection layer 5 and the wall 3 are separated by a gap G. Under a condition in which the protection layer 5 is only disposed on the light emitting chip 4, the gap G is a distance between the protection layer 5 on the side light emitting surface 41 and the inner side surface of the wall 3. Under a condition in which the protection layer 5 is disposed on the light emitting chip 4 and a part of the substrate 1, the gap G is a distance between an outer edge of the protection layer 5 and the inner side surface 30 of the wall 3.

The design of the gap G enables a part of the reflection layer 6 to cover the substrate 1 and ensures a sufficient contact area between the reflection layer 6 and the substrate 1. Specifically, a width of the gap G ranges from 30 μm to 2 mm. When the width of the gap G is larger than 2 mm, the light emitting chip 4 cannot be protected. When the width of the gap G is smaller than 30 μm, a large part of the reflection layer 6 contacts the protection layer 5, which causes an insufficient contact area between the reflection layer 6 and the substrate 1. Hence, the reflection layer 6 may peel off from the substrate 1.

It should be noted that regardless of whether the protection layer 5 is continuously or discontinuously disposed on the mounting surface 10, the protection layer 5 and the wall 3 need to be separated by the gap G.

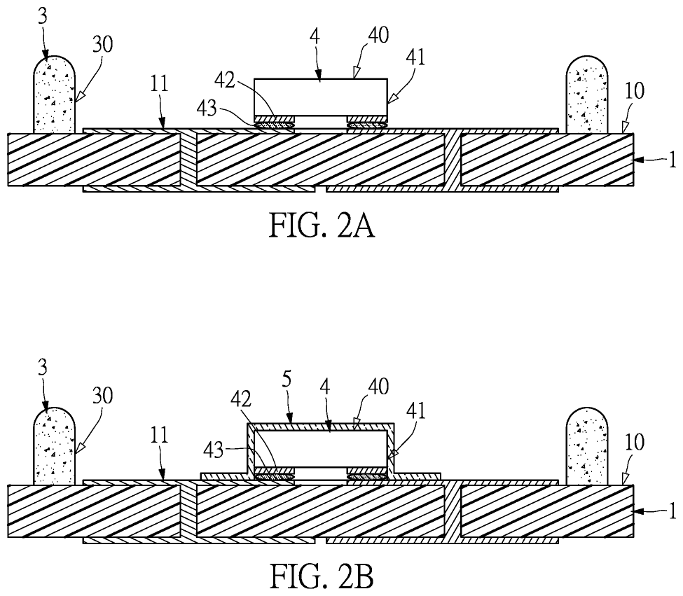

Referring to FIG. 2A, in a process for manufacturing the light emitting device of the present disclosure, the wall 3 is disposed on the substrate 1 that is mounted with the conductive circuit structure 11, such that the accommodation space is defined. The light emitting chip 4 is disposed in the accommodation space, and is electrically connected to an outer circuit via the solder pad 42, the metal solder 43, and the conductive circuit structure 11. Subsequently, the material of the protection layer 5 is prepared. The material of the protection layer 5 is disposed onto the top light emitting surface 40 and the side light emitting surface 41 in a dispensing manner.

Referring to FIG. 2B, after the formation of the protection layer 5 onto the light emitting chip 4, the material of the reflection layer 6 is prepared. The material of the reflection layer 6 is disposed onto the mounting surface 10 and filled in the accommodation space, such that the reflection layer 6 can contact a part of the mounting surface 10 (the conductive circuit structure 11), the wall 3, and the protection layer 5. Finally, the light emitting device as shown in FIG. 1 can be obtained.

### First Embodiment

Referring to FIG. 1, the light emitting device of the first embodiment of the present disclosure includes the substrate 1, the wall 3, the light emitting chip 4, the protection layer 5, and the reflection layer 6.

In the first embodiment, the substrate 1 is an aluminum oxide substrate. The conductive circuit structure 11 is disposed on the mounting surface 10 of the substrate 1. The wall 3 and the light emitting chip 4 are disposed on the mounting surface 10. The solder pad 42 is disposed on a bottom of the light emitting chip 4, and the solder pad 42 is disposed on the mounting surface 10 via the metal solder 43. The light emitting chip 4, the protection layer 5, and the reflection layer 6 are surrounded by the wall 3. The height of the wall 3 is higher than the height of the light emitting chip 4. The protection layer 5 is disposed on the top light emitting surface 40 and the side light emitting surface 41 of the light emitting chip 4, and extends from the side light emitting surface 41 toward the solder pad 42, the metal solder 43 so as to encapsulate the light emitting chip 4. The reflection layer 6 is disposed between the wall 3 and the light emitting chip 4.

Specifically, in addition to the top light emitting surface 40 and the side light emitting surface 41, the protection layer 5 is further disposed on the mounting surface 10 that surrounds the light emitting chip 4, but does not contact the wall 3. An edge of the protection layer 5 and the wall 3 are separated by the gap G, so as to ensure a sufficient contact area between the reflection layer 6 and the substrate 1. In the first embodiment, the gap G is larger than 200 μm.

The reflection layer 6 is disposed around the light emitting chip 4, and contacts the protection layer 5, a part of the mounting surface 10 (the conductive circuit structure 11), and the inner surface 30. The reflection layer 6 has a concave surface above the mounting surface 10.

### Second Embodiment

Referring to FIG. 3 and FIG. 4, the light emitting device of the second embodiment of the present disclosure includes: the substrate 1, the wall 3, the light emitting chips 4, the protection layer 5, the reflection layer 6, and a Zener chip 7.

The light emitting device of the second embodiment is similar to the light emitting device of the first embodiment. The difference is that the light emitting device of the second embodiment further includes the Zener chip 7 disposed on the mounting surface 10, and there is more than one light emitting chip 4.

In the second embodiment, the protection layer 5 is disposed on the top light emitting surface 40 and the side light emitting surface 41 of each the light emitting chips 4, and is further disposed on a top surface and a side surface of the Zener chip 7. Moreover, the protection layer 5 is continuously disposed on the mounting surface 10. The protection layers 5 covering the light emitting chip 4 and the Zener chip 7 are connected to each other to form a continuous structure. However, the protection layer 5 and the wall 3 are still separated by the gap G. In the second embodiment, the gap G is larger than 200 μm.

Apart from being disposed on and among the protection layer 5, a part of the mounting surface 10 (the conductive circuit structure 11) and the inner surface 30, the reflection layer 6 is further disposed between adjacent ones of the light emitting chips 4.

### Third Embodiment

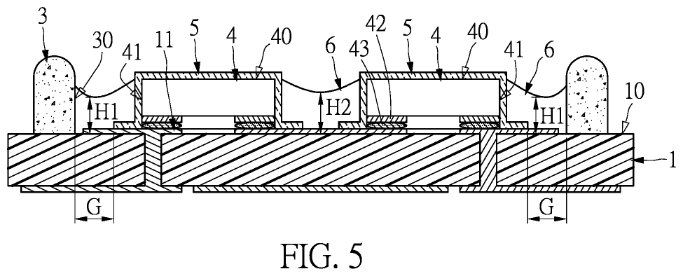

Referring to FIG. 5 and FIG. 6, the light emitting device of the third embodiment of the present disclosure includes: the substrate 1, the wall 3, the light emitting chips 4, the protection layer 5, the reflection layer 6, and the Zener chip 7.

The light emitting device of the third embodiment is similar to the light emitting device of the second embodiment. The difference is that the top surface and the side surface of the Zener chip 7 are not covered by the protection layer 5, and the protection layers 5 covering the light emitting chips 4 are not connected to each other.

Referring to FIG. 6, the protection layers 5 are discontinuously disposed on the mounting surface 10. Specifically, in addition to being disposed on the top light emitting surface 40 and the side light emitting surface 41, the protection layer 5 is further disposed on the mounting surface 10 around the light emitting chips 4. However, the protection layers 5 covering the adjacent light emitting chips 4 are not connected to each other. Moreover, the protection layer 5 does not contact the wall 3. The protection layer 5 and the wall 3 are separated by the gap G. In the third embodiment, the gap G is larger than 200 μm.

### Fourth Embodiment

Referring to FIG. 7, the light emitting device of the fourth embodiment of the present disclosure includes: the substrate 1, the wall 3, the light emitting chips 4, the protection layer 5, the reflection layer 6, and the Zener chip 7.

The light emitting device of the fourth embodiment is similar to the light emitting device of the third embodiment. The difference is that the protection layer 5 is disposed on the top surface and the side surface of the Zener chip 7, but the protection layer 5 on the Zener chip 7 is not connected to the protection layer 5 disposed on the other light emitting chips 4. Therefore, the protection layer 5 is discontinuously disposed on the mounting surface 10.

### Fifth Embodiment

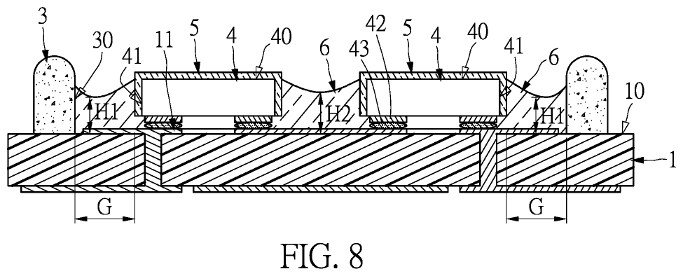

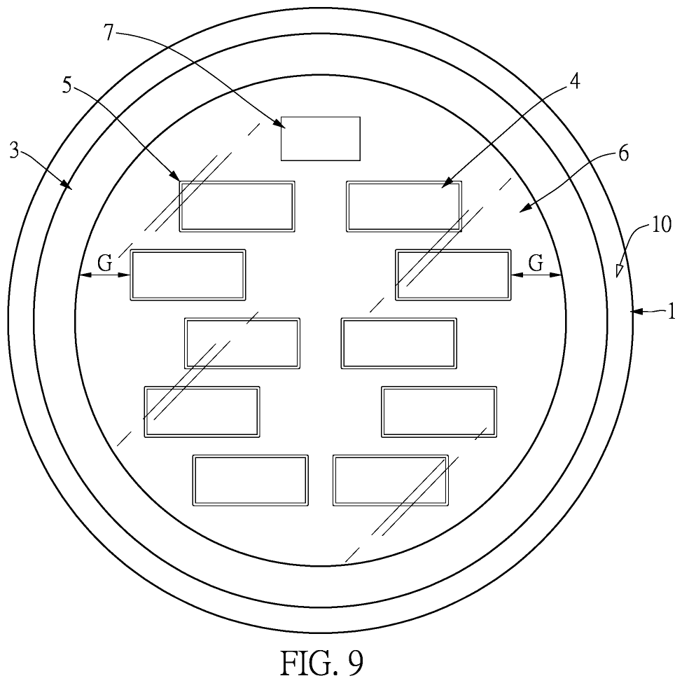

Referring to FIG. 8 and FIG. 9, the light emitting device of the fifth embodiment of the present disclosure includes: the substrate 1, the wall 3, the light emitting chips 4, the protection layer 5, the reflection layer 6, and the Zener chip 7.

The light emitting device of the fifth embodiment is similar to the light emitting device of the third embodiment. The difference is that the protection layer 5 is only disposed on the top light emitting surface 40 and the side light emitting surface 41 of each of the light emitting chips 4, without extending to the solder pad 42 or the metal solder 43 at the bottom of the light emitting chip 4 and the mounting surface 10 around the light emitting chip 4.

### First Comparative Embodiment

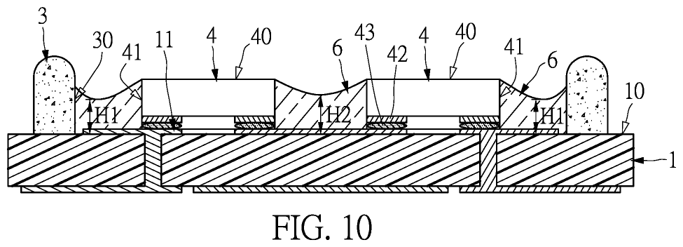

Referring to FIG. 10, the light emitting device of a first comparative embodiment includes: the substrate 1, the wall 3, the light emitting chips 4, the protection layer 5, the reflection layer 6, and the Zener chip 7. The difference between the first comparative embodiment and the second embodiment is that the protection layer 5 is absent from the light emitting device.

### Second Comparative Embodiment

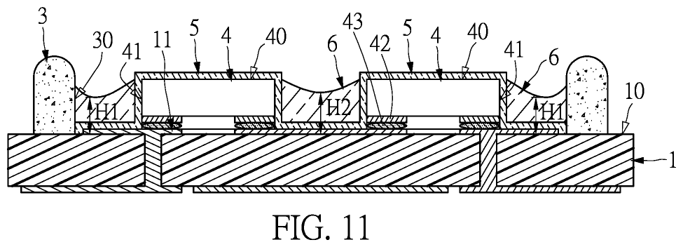

Referring to FIG. 11, the light emitting device of a second comparative embodiment includes: the substrate 1, the wall 3, the light emitting chips 4, the protection layer 5, the reflection layer 6, and the Zener chip 7. The difference between the second comparative embodiment and the second embodiment is that the protection layer 5 is not disposed only on the mounting surface 10 around the light emitting chip 4, but is covered upon an entirety of the mounting surface 10.

Specifically, the protection layer 5 is disposed on the light emitting chips 4, the Zener chip 7, and the entire mounting surface 10. In the second comparative embodiment, there is no gap G between the protection layer 5 and the wall 3, and the protection layer 5 contacts the wall 3. Therefore, the reflection layer 6 does not contact the substrate 1 (the conductive circuit structure 11).

### Data Experiment

In order to prove that the light emitting device of the present disclosure has good reliability and peeling strength, light emitting devices are manufactured according to the second embodiment, the fourth embodiment, the fifth embodiment, the first comparative embodiment, and the second comparative embodiment. In the above-mentioned light emitting devices, the light emitting chip 4 is a UV light emitting diode, the material of the protection layer 5 is a fluorine resin, and the material of the reflection layer 6 includes 100 phr of a methyl silicon resin and 20 phr to 50 phr of PTFE particles.

The light emitting devices mentioned above are subjected to a luminous efficiency test, a peeling strength test, and a reliability test. The results are listed in Table 1.

In the luminous efficiency test, a power supply unit having a power of 5.4 W is used. The light emitting device is powered by the power supply unit with a voltage of 12 V and a current of 450 mA to generate a light beam. A light intensity of the light emitting device of the second embodiment is defined as 100%, so as to evaluate the luminous efficiency of each light emitting device.

In the peeling strength test, the light emitting device is placed under a high-temperature environment of 240° C. for 5 seconds to 10 seconds. Subsequently, the protection layer 5 is clamped by a clip and then torn by a force of 100 grams, so as to evaluate the peeling strength of the light emitting device. If the structure of the light emitting device remains its original structural integrity and is not delaminated, the light emitting device is marked with the term “PASS”. If the light emitting device is delaminated, the light emitting device is marked with the term “FAIL”.

In the reliability test, the light emitting device is electrified for illumination by a current of 450 mA at a room temperature environment (25° C.), so as to evaluate the reliability of the light emitting device. If the light emitting device can maintain its structural integrity and have a luminous attenuation lower than 30% after 1000 hours of continuous illumination, the light emitting device is marked with the term “PASS”. If the light emitting device cannot maintain its structural integrity or have a luminous attenuation higher than or equal to 30%, the light emitting device is marked with the term “FAIL”.

TABLE 1

| | First | Second | | | |
|---|---|---|---|---|---|
| | Comparative | Comparative | Second | Fourth | Fifth |
| | Example | Example | Example | Example | Example |
| Structure of | without | completely | continuously | discontinuously | only |
| protection | protection | covering | disposed | disposed on | disposed |
| layer | layer | mounting | on mounting | mounting | on the light |
| | | surface | surface | surface | emitting chip |
| Luminous | 83% | 100% | 100% | 100% | 100% |
| efficiency test | | | | | |
| Peeling | PASS | FAIL | PASS | PASS | PASS |
| strength test | | | | | |
| Reliability | FAIL | PASS | PASS | PASS | PASS |
| test | (504 hours) | | | | |

According to the results in Table 1, the disposition of the protection layer 5 can protect the light emitting chip 4, such that the light emitting device can pass the reliability test. When the mounting surface 10 is completely covered by the protection layer 5, i.e., there is no gap between the protection layer 5 and the wall 3, the peeling strength of the light emitting device is decreased. Therefore, in order to uphold the reliability and the peeling strength, the protection layer 5 is disposed on the light emitting chip 4, and the protection layer 5 and the wall 3 are separated by the gap G.

### Beneficial Effects of the Embodiments

In conclusion, in the light emitting device provided by the present disclosure, by virtue of “a protection layer being disposed on the top light emitting surface and the side light emitting surface” and “a gap being formed between the protection layer and the wall,” the light emitting device can have good reliability and peeling strength.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A light emitting device, comprising:
a substrate having a mounting surface;
a wall disposed on the mounting surface and having an inner side surface, wherein an accommodation space is defined by the inner side surface and the mounting surface;
at least one light emitting chip disposed on the mounting surface and in the accommodation space, wherein the light emitting chip has a top light emitting surface and a side light emitting surface;
a protection layer disposed on the top light emitting surface and the side light emitting surface, wherein a gap is formed between the protection layer and the wall; and
a reflection layer disposed in the accommodation space and between the inner side surface and the side light emitting surface, wherein the reflection layer is filled in the gap and contacts the mounting surface.

2. The light emitting device according to claim 1, wherein a width of the gap ranges from 30 μm to 2 mm.

3. The light emitting device according to claim 1, wherein the substrate further includes a conductive circuit structure, and a part of the conductive circuit structure is covered by the protection layer.

4. The light emitting device according to claim 1, wherein a quantity of the at least one light emitting chip is more than one, and the top light emitting surface and the side light emitting surface of each of the light emitting chips are covered by the protection layer.

5. The light emitting device according to claim 4, wherein the protection layer is continuously disposed on the mounting surface.

6. The light emitting device according to claim 4, wherein the protection layer is discontinuously disposed on the mounting surface.

7. The light emitting device according to claim 1, further comprising a Zener chip, wherein the Zener chip is disposed on the mounting surface.

8. The light emitting device according to claim 7, wherein the Zener chip is covered by the protection layer.

9. The light emitting device according to claim 1, wherein, relative to the mounting surface, a height of the wall is greater than or equal to a height of the light emitting chip.

10. The light emitting device according to claim 1, wherein a thickness of the reflection layer ranges from 250 μm to 400 μm.

11. The light emitting device according to claim 1, wherein the reflection layer has a concave surface formed between the light emitting chip and the wall.

12. The light emitting device according to claim 11, wherein, relative to the mounting surface, a lowest height of the reflection layer is greater than half of a height of the light emitting chip.

13. The light emitting device according to claim 1, wherein a material of the protection layer is selected from the group consisting of a fluorine resin, a silicone oil, and silicon dioxide.

14. The light emitting device according to claim 1, wherein a material of the reflection layer includes a silicone-base resin, a UV absorber, and light reflective particles.

15. The light emitting device according to claim 14, wherein, based on a total weight of the silicone-base resin being 100 phr, an amount of the UV absorber ranges from 0.1 phr to 15 phr.

16. The light emitting device according to claim 14, wherein, based on a total weight of the silicone-base resin being 100 phr, an amount of the light reflective particles ranges from 25 phr to 50 phr.

17. The light emitting device according to claim 14, wherein a material of the reflection layer further includes a hindered amine light stabilizer.

18. The light emitting device according to claim 17, wherein, based on a total weight of the silicone-base resin being 100 phr, an amount of the hindered amine light stabilizer ranges from 0.1 phr to 15 phr.

19. The light emitting device according to claim 14, wherein the silicone-base resin is a methyl silicon resin, a methyl phenyl vinyl silicon resin, or a combination thereof.
